(19) United States
(12) Patent Application Publication
(10) Pub. No.: US 2025/0221176 A1
(43) Pub. Date: Jul. 3, 2025

(54) DISPLAY DEVICE AND METHOD OF MANUFACTURING THE DISPLAY DEVICE

(71) Applicant: Samsung Display Co., Ltd., Yongin-si (KR)

(72) Inventor: Seho Lee, Yongin-si (KR)

(21) Appl. No.: 19/005,230

(22) Filed: Dec. 30, 2024

(30) Foreign Application Priority Data
Jan. 2, 2024 (KR) 10-2024-0000490

(51) Int. Cl. H10K 59/122; H10K 59/12; H10K 102/00

(52) U.S. Cl. CPC H10K 59/122; H10K 59/1201; H10K 2102/351

(57) ABSTRACT

A display device includes a substrate, a sub-pixel electrode above the substrate, a pixel-defining layer partially above the sub-pixel electrode, an intermediate layer partially above the pixel-defining layer, and defining a hole exposing at least a portion of the sub-pixel electrode, and an opposite electrode partially above the intermediate layer, wherein a first side surface defining the hole, which is adjacent to an edge portion of the sub-pixel electrode, includes a side surface of the pixel-defining layer and a side surface of the intermediate layer.

### CROSS-REFERENCE TO RELATED APPLICATION

The present application claims priority to, and the benefit of, Korean Patent Application No. 10-2024-0000490, filed on Jan. 2, 2024, in the Korean Intellectual Property Office, the entire disclosure of which is incorporated herein by reference.

### BACKGROUND

### 1. Field

One or more embodiments relate to a display device, and a method of manufacturing the display device.

### 2. Description of the Related Art

A display device visually displays data. The display device may provide an image by using light-emitting diodes. As the use of display devices has become diversified, various designs have been attempted to improve the quality of the display devices.

### SUMMARY

One or more embodiments include a display device, and a method of manufacturing the display device.

Additional aspects will be set forth in part in the description which follows and, in part, will be apparent from the description, or may be learned by practice of the presented embodiments of the disclosure.

According to one or more embodiments, a display device includes a substrate, a sub-pixel electrode above the substrate, a pixel-defining layer partially above the sub-pixel electrode, an intermediate layer partially above the pixel-defining layer, and defining a hole exposing at least a portion of the sub-pixel electrode, and an opposite electrode partially above the intermediate layer, wherein a first side surface defining the hole, which is adjacent to an edge portion of the sub-pixel electrode, includes a side surface of the pixel-defining layer and a side surface of the intermediate layer.

The hole may correspond to an area where the sub-pixel electrode and the opposite electrode contact each other.

A thickness of the side surface of the pixel-defining layer may be about 2,000 Å or less.

A thickness of the side surface of the pixel-defining layer may be about 100 Å or more and about 2,000 Å or less.

A length of the hole in a first direction may be about 3 μm or more and about 15 μm or less.

A second side surface of the hole, which is spaced apart from the first side surface in the first direction, may include only a side surface of the intermediate layer.

The second side surface of the hole might not include a surface of the pixel-defining layer.

The intermediate layer may include an emission layer and a functional layer.

According to one or more embodiments, a method of manufacturing a display device includes forming a hole by irradiating a laser beam to a pixel-defining layer and an intermediate layer above an upper surface of a sub-pixel electrode, and forming an opposite electrode on the sub-pixel electrode, wherein a thickness of a portion of the pixel-defining layer above the sub-pixel electrode is about 2,000 Å or less.

The thickness of the portion of the pixel-defining layer may be about 100 Å or more.

The forming of the hole may include removing, by irradiating the laser beam, another portion of the pixel-defining layer and a portion of the intermediate layer above the sub-pixel electrode.

The forming of the hole may include concurrently removing, by irradiating the laser beam, another portion of the pixel-defining layer and a portion of the intermediate layer above the sub-pixel electrode.

The hole may correspond to an area in which the sub-pixel electrode and the opposite electrode contact each other.

A length of the hole may be about 3 μm or more and about 15 μm or less.

A length of an area where the pixel-defining layer is above the sub-pixel electrode may be about 1 μm or more.

A length between an end of the sub-pixel electrode and an end of the pixel-defining layer above the sub-pixel electrode may be about 1 μm or more.

The intermediate layer may include an emission layer and a functional layer.

A wavelength of the laser beam may correspond to an ultraviolet area.

A wavelength of the laser beam may be about 300 nm or more and about 400 nm or less.

An intensity of the laser beam may be about 200 mJ/cm² or less.

### BRIEF DESCRIPTION OF THE DRAWINGS

The above and other aspects of embodiments of the disclosure will be more apparent from the following description taken in conjunction with the accompanying drawings, in which:

FIG. 1 is a schematic perspective view of a display device according to one or more embodiments;

FIG. 2 is a schematic cross-sectional view of a display panel according to one or more embodiments;

FIG. 3 is a schematic equivalent circuit diagram of any one sub-pixel circuit provided in a display device according to one or more embodiments;

FIG. 4 is a schematic cross-sectional view of a display device according to one or more embodiments;

FIG. 5 is a schematic cross-sectional view of a display panel in the case where the thickness of at least a portion of a pixel-defining layer located on the upper surface of a sub-pixel circuit exceeds about 2,000 Å;

FIG. 6A is a cross-sectional view showing a method of manufacturing a display device;

FIG. 6B is an enlarged view schematically showing a region A of FIG. 6A; and

FIGS. 7 and 8 are cross-sectional views showing a method of manufacturing a display device.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

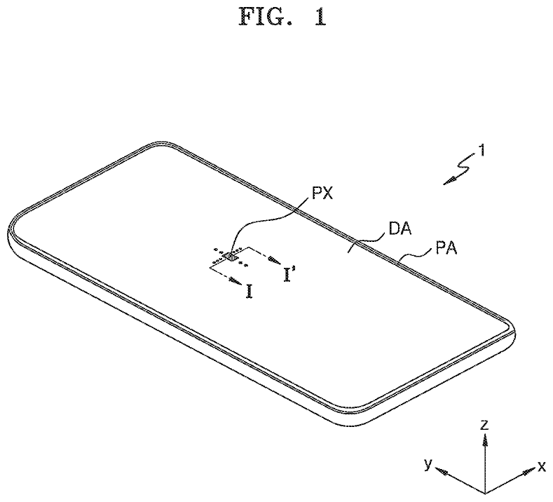

FIG. 1 is a schematic perspective view of a display device according to one or more embodiments;

A display device according to embodiments is a device that displays a video or a still image, which may be a portable electronic device, such as a mobile phone, a smartphone, a tablet personal computer (PC), a mobile communication terminal, an electronic notebook, an electronic book, a portable multimedia player (PMP), a navigation device, an Ultra Mobile PC (UMPC), or the like, and may also be used as a display screen of various products, such as a television, a laptop computer, a monitor, an advertisement board, an Internet of things (IoT) device, or the like. In addition, the display device according to one or more embodiments may be used as a wearable device, such as a smartwatch, a watch phone, a glasses-type display, and a head-mounted display (HMD). Also, the display device according to one or more embodiments may be used as a dashboard of a vehicle, a center fascia of a vehicle or a center information display (CID) located on a dashboard, a rear mirror display replacing a side mirror of a vehicle, and a display arranged on a back surface of a front seat as entertainment for a passenger on a back seat of a vehicle.

Referring to FIG. 1, a display device 1 may have an edge in a first direction and an edge in a second direction. Here, the first direction and the second direction may be directions intersecting with each other. For example, the first direction and the second direction may form an acute angle with each other. As another example, the first direction and the second direction may form an obtuse angle with each other, or may be orthogonal to each other. Hereinafter, a case where the first direction and the second direction are orthogonal to each other is mainly described in detail. For example, the first direction may be an x direction or −x direction, and the second direction may be a y direction or −y direction. A third direction perpendicular to the first direction and the second direction may be a z direction or −z direction.

The display device 1 may include a display area DA, and a peripheral area PA outside the display area DA. The display device 1 may provide an image by using light emitted from a plurality of sub-pixels PX arranged in the display area DA. The peripheral area PA is an area outside the display area DA, and may be a type of non-display area in which sub-pixels are not arranged. The display area DA may be entirely surrounded by the peripheral area PA.

Hereinafter, an organic light-emitting display device is described as an example of the display device 1 according to one or more embodiments. However, the display device 1 is not limited thereto. As one or more other embodiments, the display device 1 may be a display device, such as an inorganic light-emitting display device, an inorganic electroluminescence (EL) display device, or a quantum dot light-emitting device. For example, an emission layer of a display element included in the display device 1 may also include an organic material or an inorganic material. In addition, the display device 1 may also include an emission layer and a quantum dot positioned on a path of light emitted by the emission layer.

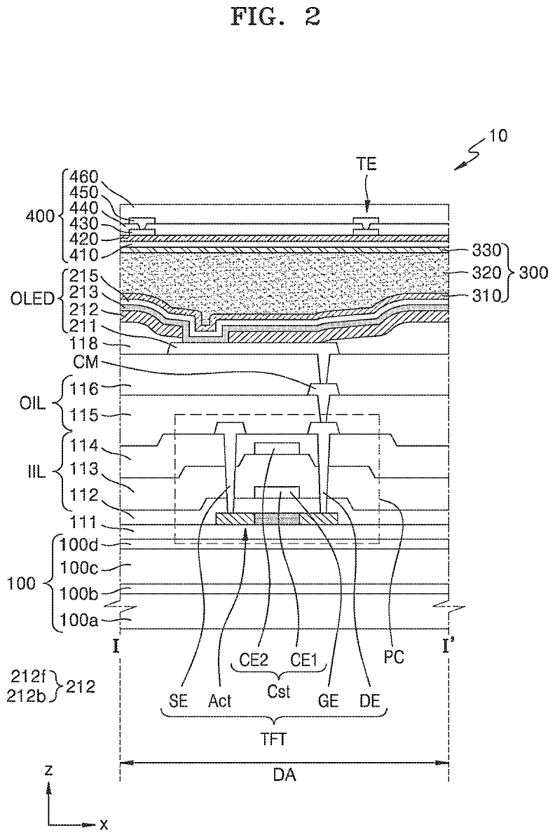

FIG. 2 is a schematic cross-sectional view of a display panel according to one or more embodiments. For example, FIG. 2 is a schematic cross-sectional view of a display area of a display device according to one or more embodiments.

Referring to FIG. 2, a display panel 10 may include a substrate 100, an inorganic insulating layer IIL, an organic insulating layer OIL, a sub-pixel circuit PC, a connection electrode CM, an organic light-emitting diode OLED, a pixel-defining layer 118, a spacer 119, and an encapsulation layer 300. That is, the substrate 100, the inorganic insulating layer IIL, the organic insulating layer OIL, the sub-pixel circuit PC, the connection electrode CM, the organic light-emitting diode OLED, the pixel-defining layer 118, the spacer 119, and the encapsulation layer 300 may be arranged in the display area DA of the display panel 10.

For example, the substrate 100 may include a first base layer 100a, a first barrier layer 100b, a second base layer 100c, and a second barrier layer 100d. In one or more embodiments, the first base layer 100a, the first barrier layer 100b, the second base layer 100c, and the second barrier layer 100d may be sequentially stacked in a thickness direction of the substrate 100.

At least one of the first base layer 100a and the second base layer 100c may include a polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, or the like.

The first barrier layer 100b and the second barrier layer 100d are barrier layers configured to reduce or prevent penetration of external foreign substances, and may each be a single layer or a multi-layer, each including an inorganic material, such as silicon nitride (SiNₓ), silicon oxide (SiOₓ), and/or silicon oxynitride (SiON).

A buffer layer 111 may be located on the substrate 100 (as used herein “located on” or “on” may mean “above”). The buffer layer 111 may include an inorganic insulating material, such as silicon nitride (SiN_{X}), silicon oxynitride (SiON), or silicon oxide (SiO₂), and may include a single layer or a multi-layer, each including the inorganic insulating material stated above.

The inorganic insulating layer IIL may be located on the buffer layer 111. The inorganic insulating layer IIL may include a first inorganic insulating layer 112, a second inorganic insulating layer 113, and a third inorganic insulating layer 114.

The sub-pixel circuit PC may be arranged in the display area DA. The sub-pixel circuit PC may include a thin-film transistor TFT and a storage capacitor Cst. The thin-film transistor TFT may include a semiconductor layer Act, a gate electrode GE, a source electrode SE, and a drain electrode DE.

The semiconductor layer Act may be located on the buffer layer 111. The semiconductor layer Act may include polysilicon. Alternatively, the semiconductor layer Act may include amorphous silicon, an oxide semiconductor, an organic semiconductor, or the like. The semiconductor layer Act may include a channel area, a drain area, and a source area, the drain area and the source area being respectively arranged on both sides of the channel area.

The gate electrode GE may be located above the semiconductor layer Act. The gate electrode GE may overlap the channel are of the semiconductor layer ACT. The gate electrode GE may include a low-resistance metal material. The gate electrode GE may include a conductive material including molybdenum (Mo), aluminum (Al), copper (Cu), titanium (Ti), or the like, and may include a multi-layer or a single layer, each including the above-stated material.

The first inorganic insulating layer 112 may be between the semiconductor layer Act and the gate electrode GE. The first inorganic insulating layer 112 may include an inorganic insulating material, such as silicon oxide (SiO₂), silicon nitride (SiN_{X}), silicon oxynitride (SiON), aluminum oxide (Al₂O₃), titanium oxide (TiO₂), tantalum pentaoxide (Ta₂O₅), hafnium oxide (HfO₂), zinc oxide (ZnO), or the like.

The second inorganic insulating layer 113 may be located on the gate electrode GE. The second inorganic insulating layer 113 may be provided to cover the gate electrode GE. The second inorganic insulating layer 113 may include an inorganic insulating material, such as silicon oxide (SiO₂), silicon nitride (SiN_{X}), silicon oxynitride (SiON), aluminum oxide (Al₂O₃), titanium oxide (TiO₂), tantalum pentaoxide (Ta₂O₅), hafnium oxide (HfO₂), zinc oxide (ZnO), or the like.

An upper electrode CE2 of the storage capacitor Cst may be located on the second inorganic insulating layer 113. The upper electrode CE2 may overlap the gate electrode GE located below the upper electrode CE2. At this time, the gate electrode GE and the upper electrode CE2, which overlap each other with the second inorganic insulating layer 113 therebetween, my form the storage capacitor Cst. That is, the gate electrode GE may function as a lower electrode CE1 of the storage capacitor Cst.

As such, the storage capacitor Cst and the thin-film transistor TFT may overlap each other. However, the disclosure is not limited thereto. For example, the storage capacitor Cst may not overlap the thin-film transistor TFT. That is, the lower electrode CE1 of the storage capacitor Cst is a separate component with the gate electrode GE of the thin-film transistor TFT, and may be provided to be spaced apart from the gate electrode GE of the thin-film transistor TFT.

The upper electrode CE2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu, and may include a single layer or a multi-layer, each including the above-stated material.

The third inorganic insulating layer 114 may be located on the upper electrode CE2. The third inorganic insulating layer 114 may cover the upper electrode CE2. The third inorganic insulating layer 114 may include an inorganic insulating material, such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), zinc oxide (ZnO), or the like. The third inorganic insulating layer 114 may be a single layer or a multi-layer, each including the above-stated inorganic insulating material.

Each of the drain electrode DE and the source electrode SE may be positioned on the third inorganic insulating layer 114. Each of the drain electrode DE and the source electrode SE may be connected to the semiconductor layer Act through contact holes provided in the first inorganic insulating layer 112, the second inorganic insulating layer 113, and the third inorganic insulating layer 114. Each of the drain electrode DE and the source electrode SE may include a material having good conductivity. Each of the drain electrode DE and the source electrode SE may include a conductive material including Mo, Al, Cu, Ti, or the like, and may include a multi-layer or a single layer, each including the above-stated material. For example, each of the drain electrode DE and the source electrode SE may include a multi-layered structure of Ti/Al/Ti.

The organic insulating layer OIL may be located on the inorganic insulating layer IIL. The organic insulating layer OIL may include a first organic insulating layer 115 and a second organic insulating layer 116. FIG. 2 shows that the organic insulating layer OIL includes two organic insulating layers, but the disclosure is not limited thereto. The organic insulating layer OIL may also include three or four organic insulating layers, for example.

The first organic insulating layer 115 may cover the drain electrode DE and the source electrode SE. The first organic insulating layer 115 may include a general commercial polymer, such as poly (methyl methacrylate) (PMMA) or polystyrene (PS), a polymer derivative having a phenol group, and an organic insulating material, such as an acrylic polymer, an imide polymer, an aryl ether polymer, an amide polymer, a fluorine polymer, a p-xylene polymer, a vinyl alcohol polymer, or a mixture thereof.

The connection electrode CM may be located on the first organic insulating layer 115. At this time, the connection electrode CM may be connected to the drain electrode DE or the source electrode SE through a contact hole in the first organic insulating layer 115. The connection electrode CM may include a material having good conductivity. The connection electrode CM may include a conductive material including Mo, Al, Cu, Ti, or the like, and may include a multi-layer or a single layer including the above-stated material. For example, the connection electrode CM may have a multi-layered structure of Ti/Al/Ti.

The second organic insulating layer 116 may be located on the connection electrode CM. The second organic insulating layer 116 may cover the connection electrode CM. The second organic insulating layer 116 may include the same material as the first organic insulating layer 115 or a different material.

A light-emitting diode may be located on the second organic insulating layer 116. For example, the organic light-emitting diode OLED may be located on the second organic insulating layer 116. Alternatively, in one or more embodiments, an inorganic light-emitting diode or the like may also be located on the second organic insulating layer 116.

The organic light-emitting diode OLED may emit red, green, or blue light, or may emit red, green, blue, or white light. The organic light-emitting diode OLED may include a sub-pixel electrode 211, an intermediate layer 212, an opposite electrode 213, and a capping layer 215.

The sub-pixel electrode 211 may be located on the second organic insulating layer 116. The sub-pixel electrode 211 may be electrically connected to the connection electrode CM through a contact hole defined in the second organic insulating layer 116. The sub-pixel electrode 211 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In one or more embodiments, the sub-pixel electrode 211 may include a reflective film including Ag, Mg, Al, Pt, Pd, Au, Ni, Nd, Ir, Cr, or a compound thereof. In one or more embodiments, the sub-pixel electrode 211 may further include a film including ITO, IZO, ZnO, or In₂O₃ above and/or below the reflective film described above. For example, the sub-pixel electrode 211 may have a multi-layered structure of ITO/Ag/ITO.

The pixel-defining layer 118, in which an opening exposing at least a portion of the sub-pixel electrode 211 is defined, may be located on the sub-pixel electrode 211. The opening defined in the pixel-defining layer 118 may define an emission area of light emitted from the organic light-emitting diode OLED. For example, the width of the opening may correspond to the width of the emission area.

The pixel-defining layer 118 may include an organic insulating material. Alternatively, the pixel-defining layer 118 may include an inorganic insulating material, such as silicon nitride, silicon oxynitride, or silicon oxide. Alternatively, the pixel-defining layer 118 may include an organic insulating material and an inorganic insulating material. In one or more embodiments, the pixel-defining layer 118 may include a light-blocking material. The light-blocking material may include carbon black, carbon nanotubes, a resin or paste including a black dye, metal particles, such as nickel, aluminum, molybdenum, or alloys thereof, metal oxide particles (e.g., chromium oxide), metal nitride particles (e.g., chromium nitride), or the like. When the pixel-defining layer 118 includes a light-blocking material, reflection of external light by metal structures located on a lower portion of the pixel-defining layer 118 may be reduced.

The spacer 119 may be located on the pixel-defining layer 118. The spacer 119 may include an organic insulating material, such as polyimide. Alternatively, the spacer 119 may include an inorganic insulating material, such as silicon nitride (SiN_{X}) or silicon oxide (SiO₂), or may include an organic insulating material and an inorganic insulating material.

In one or more embodiments, the spacer 119 may include the same material the pixel-defining layer 118. In this case, the pixel-defining layer 118 and the spacer 119 may be formed together in a mask operation using a halftone mask or the like. Alternatively, the spacer 119 may include a material different from that of the pixel-defining layer 118.

The intermediate layer 212 may include an emission layer. For example, the emission layer may be arranged in the opening of the pixel-defining layer 118. The emission layer may include a polymer organic material or a low-molecular-weight organic material, which emits light of a corresponding color.

The intermediate layer 212 may include a functional layer. The functional layer may include a first functional layer and a second functional layer. The first functional layer may be between the sub-pixel electrode 211 and the emission layer, and the second functional layer may be between the emission layer and the opposite electrode 213. However, at least one of the first functional layer and the second functional layer may be omitted. Hereinafter, a case in which the first functional layer and the second functional layer are respectively arranged is mainly described in detail.

The first functional layer may include a hole transport layer (HTL) and/or a hole injection layer (HIL). The second functional layer may include an electron transport layer (ETL) and/or an electron injection layer (EIL).

The opposite electrode 213 may be located on the intermediate layer 212. The opposite electrode 213 may include a conductive material having a low work function. For example, the opposite electrode 213 may include a (semi) transparent layer, the (semi) transparent layer including Ag, Mg, Al, Pt, Pd, Au, Ni, Nd, Ir, Cr, lithium (Li), Ca, alloys thereof, or the like. Alternatively, the opposite electrode 213 may further include a layer, such as ITO, IZO, ZnO, or In₂O₃, above the (semi)transparent layer including the material stated above.

In one or more embodiments, the capping layer 215 may be located on the opposite electrode 213. The capping layer 215 may include lithium fluoride (LiF), an inorganic material, and/or an organic material.

The encapsulation layer 300 may be located on the organic light-emitting diode OLED. The encapsulation layer 300 may cover the organic light-emitting diode OLED. The encapsulation layer 300 may be located on the opposite electrode 213 and/or the capping layer 215. In one or more embodiments, the encapsulation layer 300 may include at least one inorganic film layer and at least one organic film layer. FIG. 2 illustrates that the encapsulation layer 300 includes a first inorganic encapsulation layer 310, an organic encapsulation layer 320, and a second inorganic encapsulation layer 330, which are sequentially stacked.

Each of the first inorganic encapsulation layer 310 and the second inorganic encapsulation layer 330 may include one or more inorganic materials, such as aluminum oxide, titanium oxide, tantalum oxide, hafnium oxide, zinc oxide, silicon oxide, silicon nitride, or silicon oxynitride. Each of the first inorganic encapsulation layer 310 and the second inorganic encapsulation layer 330 may be a single layer or a multi-layer, each including one or more of the materials stated above. The organic encapsulation layer 320 may include a polymer-based material. The polymer-based material may include an acrylic resin, an epoxy resin, polyimide, polyethylene, or the like. In one or more embodiments, the organic encapsulation layer 320 may include acrylate.

A touch sensor layer 400 may be located on the encapsulation layer 300. The touch sensor layer 400 may include a first touch insulating layer 410, a second touch insulating layer 420, a first conductive layer 430, a third touch insulating layer 440, a second conductive layer 450, and a planarization layer 460.

In one or more embodiments, the first touch insulating layer 410 may be located on the second inorganic encapsulation layer 330, and the second touch insulating layer 420 may be located on the first touch insulating layer 410. In one or more embodiments, each of the first touch insulating layer 410 and the second touch insulating layer 420 may include an inorganic insulating material and/or an organic insulating material. For example, each of the first touch insulating layer 410 and the second touch insulating layer 420 may include an inorganic insulating material, such as silicon oxide, silicon nitride, and/or silicon oxynitride.

In one or more embodiments, at least one of the first touch insulating layer 410 and the second touch insulating layer 420 may be omitted. For example, the first touch insulating layer 410 may be omitted. In this case, the second touch insulating layer 420 may be located on the second inorganic encapsulation layer 330, and the first conductive layer 430 may be located on the second touch insulating layer 420.

The first conductive layer 430 may be located on the second touch insulating layer 420, and the third touch insulating layer 440 may be located on the first conductive layer 430. In one or more embodiments, the third touch insulating layer 440 may include an inorganic insulating material and/or an organic insulating material. For example, the third touch insulating layer 440 may include an inorganic insulating material, such as silicon oxide, silicon nitride, and/or silicon oxynitride.

The second conductive layer 450 may be located on the third touch insulating layer 440. A touch electrode TE of the touch sensor layer 400 may be provided in a structure in which the first conductive layer 430 and the second conductive layer 450 are connected. Alternatively, the touch electrode TE may be formed on any one of the first conductive layer 430 and the second conductive layer 450, and may include a metal line provided in the corresponding conductive layer. Each of the first conductive layer 430 and the second conductive layer 450 may include at least one of Al, Cu, Ti, Mo, and ITO, and may include a single layer or a multi-layer, each including the above-stated material. For example, each of the first conductive layer 430 and the second conductive layer 450 may have a three-layer structure of a titanium layer/aluminum layer/titanium layer.

In one or more embodiments, the planarization layer 460 may cover the second conductive layer 450. The planarization layer 460 may include an organic insulating material.

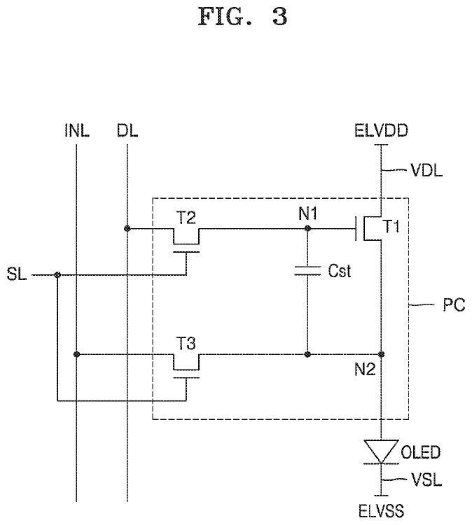

FIG. 3 is a schematic equivalent circuit diagram of any one sub-pixel circuit provided in a display device according to one or more embodiments.

Referring to FIG. 3, the sub-pixel circuit PC may include a plurality of thin-film transistors and at least one capacitor. In one or more embodiments, the sub-pixel circuit PC may include a first thin-film transistor T1, a second thin-film transistor T2, a third thin-film transistor T3, and the storage capacitor Cst.

Each of the first thin-film transistor T1, the second thin-film transistor T2, and the third thin-film transistor T3 may be an oxide semiconductor thin-film transistor including a semiconductor layer including an oxide semiconductor or a silicon semiconductor thin-film transistor including a semiconductor layer including polysilicon. Each thin-film transistor may include a first electrode and a second electrode, and according to the type of the thin-film transistor, the first electrode may be any one of a source electrode and a drain electrode, and the second electrode may be the other one of the source electrode and the drain electrode. In addition, each thin-film transistor may include a gate electrode.

The first thin-film transistor T1 may be a driving thin-film transistor. A first electrode of the first thin-film transistor T1 may be connected to a driving voltage line VDL that supplies a driving power voltage ELVDD, and a second electrode thereof may be connected to a pixel electrode of the organic light-emitting diode OLED. A gate electrode of the first thin-film transistor T1 may be connected to a first node N1. The first thin-film transistor T1 may control an amount of current flowing through the organic light-emitting diode OLED from the driving power voltage ELVDD in response to the voltage of the first node N1.

The second thin-film transistor T2 may be a switching thin-film transistor. A first electrode of the second thin-film transistor T2 may be connected to a data line DL, and a second electrode thereof may be connected to the first node N1. A gate electrode of the second thin-film transistor T2 may be connected to a scan line SL. The second thin-film transistor T2 may be turned on when a scan signal is supplied through the scan line SL to electrically connect the data line DL and the first node N1 to each other.

The third thin-film transistor T3 may be an initialization thin-film transistor and/or a sensing thin-film transistor. A first electrode of the third thin-film transistor T3 may be connected to a second node N2, and a second electrode thereof may be connected to an initialization voltage line INL. A gate electrode of the third thin-film transistor T3 may be connected to the scan line SL.

The third thin-film transistor T3 may be turned on when a scan signal is supplied through the scan line SL to electrically connect the initialization voltage line INL and the second node N2 to each other. In some embodiments, the third thin-film transistor T3 may be turned on in response to a signal received through the scan line SL from the initialization voltage line INL to initialize the pixel electrode of the organic light-emitting diode OLED to an initialization voltage.

In some embodiments, the third thin-film transistor T3 may be turned on when a scan signal is provided through the scan line SL to sense characteristic information of the organic light-emitting diode OLED. The third thin-film transistor T3 may have both a function as the initialization thin-film transistor and a function as the sensing thin-film transistor described above, or may have any one of the functions described above. An initialization operation and a sensing operation of the third thin-film transistor T3 may be performed individually or at the same time. When the third thin-film transistor T3 has a function as a sensing thin-film transistor, the initialization voltage line INL may be named as a sensing line.

The storage capacitor Cst may be connected between the first node N1 and the second node N2. For example, a first capacitor plate of the storage capacitor Cst may be connected to the gate electrode of the first thin-film transistor T1, and a second capacitor plate of the storage capacitor Cst may be connected to the pixel electrode of the organic light-emitting diode OLED.

An opposite electrode of the organic light-emitting diode OLED may be connected to a common voltage line VSL that provides a common power voltage ELVSS.

Although it is described with reference to FIG. 3 that the sub-pixel circuit PC includes three thin-film transistors and one storage capacitor, the disclosure is not limited thereto. In one or more other embodiments, the number of thin-film transistors and the number of storage capacitors may be variously changed according to the design of the sub-pixel circuit PC.

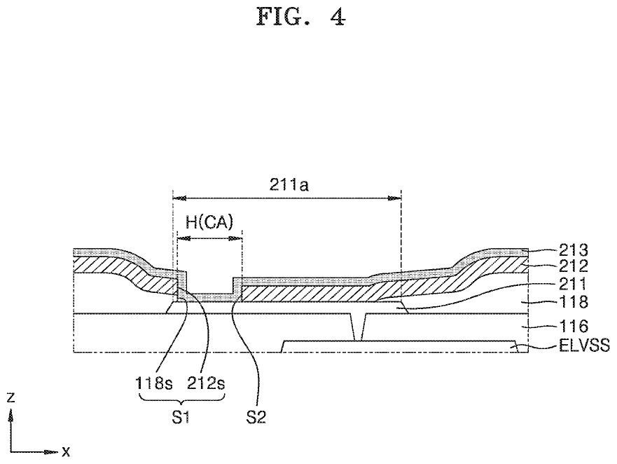

FIG. 4 is a schematic cross-sectional view of a display device according to one or more embodiments. For example, FIG. 4 schematically shows an enlarged view of the second organic insulating layer, the sub-pixel electrode, the pixel-defining layer, the intermediate layer, and the opposite electrode shown in FIG. 3.

Referring to FIG. 4, the sub-pixel electrode 211 may be located on the second organic insulating layer 116 (as used herein, “located on” may mean “above”). The pixel-defining layer 118 may be located on the sub-pixel electrode 211. At least a portion of the pixel-defining layer 118 may be located on the upper surface of the sub-pixel electrode 211. The intermediate layer 212 may be located on the pixel-defining layer 118 and the sub-pixel electrode 211. The intermediate layer 212 may include an emission layer and a functional layer.

In one or more embodiments, a hole H(CA) exposing at least a portion of the sub-pixel electrode 211 may be defined in the intermediate layer 212. The hole H (CA) may be arranged adjacent to an edge portion (or a side surface portion) of the sub-pixel electrode 211. In addition, the hole H(CA) may be formed by concurrently or substantially simultaneously removing at least a portion of the pixel-defining layer 118 and at least a portion of the intermediate layer 212, which were located on the upper surface of the sub-pixel electrode 211.

A first side surface S1 of the side surfaces of the hole H(CA) may be adjacent to the edge portion (or the side surface portion) of the sub-pixel electrode 211. Because the hole H(CA) is formed by removing at least a portion of the pixel-defining layer 118 and at least a portion of the intermediate layer 212, which are located on the upper surface of the sub-pixel electrode 211, the first side surface S1 of the hole H(CA), which is adjacent to the edge portion (or the side surface portion) of the sub-pixel electrode 211 may be provided as a side surface 118s of the pixel-defining layer 118 and a side surface 212s of the intermediate layer 212.

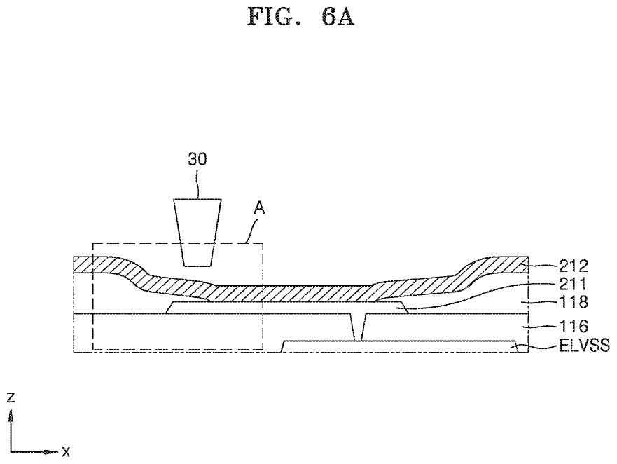

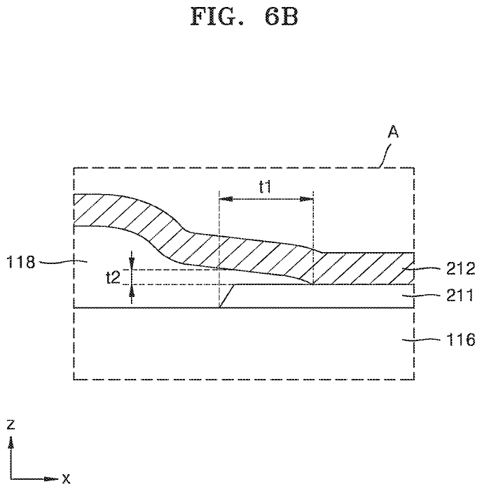

The hole H(CA) may be formed by irradiating a laser beam (refer to 30 of FIG. 6A) to at least a portion of the pixel-defining layer 118 and at least a portion of the intermediate layer 212, which are located on the upper surface of the sub-pixel electrode 211, and concurrently or substantially simultaneously removing the portion of the pixel-defining layer 118 and the portion of the intermediate layer 212, which are irradiated with the laser 30. The intensity of light irradiated by the laser 30 may be about 200 mJ/cm² or less. When the intensity of light irradiated by the laser 30 exceeds about 200 mJ/cm², the sub-pixel electrode 211 may burst, and defects may be caused in the display device. In addition, the wavelength of light irradiated by the laser 30 is the wavelength of an ultraviolet area, and may be particularly about 300 nm or more and about 400 nm or less. The laser 30 irradiating light having the wavelength of the ultraviolet area may be used to efficiently remove at least a portion of the pixel-defining layer 118 and the intermediate layer 212 without damaging the display panel.

In one or more embodiments, the thickness of the side surface 118s of the pixel-defining layer 118, which is included in the first side surface S1 of the hole H(CA), may be about 2,000 Å or less. For example, the thickness of the side surface 118s of the pixel-defining layer 118, which is included in the first side surface S1 of the hole H(CA), may be about 100 Å or more and about 2,000 Å or less.

When the laser 30 irradiates light having the wavelength of the ultraviolet area, and the intensity of light is about 200 mJ/cm² or less, the thickness of the pixel-defining layer 118 and the intermediate layer 212, which may be removed, may be about 6,000 Å or less. Because the thickness of the intermediate layer 212 is 4,000 Å, the thickness of the pixel-defining layer 118 located on the upper surface of the sub-pixel electrode 211 may be about 2,000 Å or less such that the hole H (CA) may be formed by concurrently or substantially simultaneously the pixel-defining layer 118 and the intermediate layer 212, which are located on the upper surface of the sub-pixel electrode 211. When the thickness of at least a portion of the pixel-defining layer 118, which is located on the upper surface of the sub-pixel electrode 211, exceeds about 2,000 Å, the hole H(CA) may not be formed by concurrently or substantially simultaneously removing at least a portion of the pixel-defining layer 118 and at least a portion of the intermediate layer 212, which are located on the upper surface of the sub-pixel electrode 211.

In addition, the reflective film of the sub-pixel electrode 211 may include Ag, and a layer including a conductive oxide may be located on the lower portion and the upper portion of the reflective film. When a side surface of the sub-pixel electrode 211 is exposed, because a side surface of the reflective film included in the sub-pixel electrode 211 is exposed, the reflective film including Ag may be oxidized in a manufacturing process of a display panel, and the sub-pixel electrode 211 may be dissolved. To reduce or prevent the likelihood of the dissolution of the sub-pixel electrode 211, the side surface of the reflective film of the sub-pixel electrode 211 may be covered with the pixel-defining layer 118. Because the edge portion (or the side surface portion) of the sub-pixel electrode 211 may be covered with the pixel-defining layer 118, at least a portion of the pixel-defining layer 118 may also be located on the upper surface of the sub-pixel electrode 211, which is adjacent to the edge portion (or the side surface portion) of the sub-pixel electrode 211. Accordingly, the thickness of the portion of the pixel-defining layer 118, which is located on the upper surface of the sub-pixel electrode 211, may be about 100 Å or more. When the thickness of the portion of the pixel-defining layer 118, which is located on the upper surface of the sub-pixel electrode 211, is less than about 100 Å, the side surface of the reflective film of the sub-pixel electrode 211 may not be covered with the pixel-defining layer 118, and thus the sub-pixel electrode 211 may be dissolved, and defects may occur in the display device.

A second side surface S2 of the hole H(CA), which is spaced apart from the first side surface S1 of the hole H(CA) in a first direction (e.g., an x direction or −x direction), may be provided only as a side surface of the intermediate layer 212. For example, the second side surface S2 of the hole H(CA) may not include the side surface of the pixel-defining layer 118. Because the hole H(CA) is formed by removing at least a portion of the pixel-defining layer 118 and at least a portion of the intermediate layer 212, which are located on the upper surface of the sub-pixel electrode 211, which is adjacent to the edge portion (or the side surface portion) of the sub-pixel electrode 211, the second side surface S2 of the hole H(CA) may not include a side surface of the pixel-defining layer 118, and may be provided only as a side surface of the intermediate layer 212.

The opposite electrode 213 may be located on the intermediate layer 212. Because the hole H(CA) is formed by removing at least a portion of the pixel-defining layer 118 and at least a portion of the intermediate layer 212, which are located on the upper surface of the sub-pixel electrode 211, at least a portion of the sub-pixel electrode 211 may be exposed by the hole H(CA). Accordingly, the sub-pixel electrode 211 and the opposite electrode 213 may contact each other in the hole H(CA). In other words, the hole H(CA) may be an area where the sub-pixel electrode 211 and the opposite electrode 213 contact each other. The common power voltage ELVSS may be applied to the sub-pixel electrode 211. In the case of a large display, an increase in resistance due to the thin opposite electrode 213 may result in a voltage drop (IR drop) phenomenon when power is applied to the sub-pixel circuit PC. The increase in resistance due to the thin opposite electrode 213 may be compensated by contacting the opposite electrode 213 and the sub-pixel electrode 211 applied with the common power voltage ELVSS with each other, and the reliability of the display device may be secured.

The length of the hole H(CA) in the first direction may be about 3 μm or more and about 15 μm or less. In other words, a length of an area where the sub-pixel electrode 211 and the opposite electrode 213 contact each other, in the first direction (e.g., the x direction or −x direction), may be about 3 μm or more and about 15 μm or less. The hole H(CA) may be formed by irradiating light to at least a portion of the pixel-defining layer 118 and at least a portion of the intermediate layer 212, which are located on the upper surface of the sub-pixel electrode 211, through a laser, and by removing the portion of the pixel-defining layer 118 and the portion of the intermediate layer 212, which are irradiated by light. When at least a portion of the pixel-defining layer 118 and at least a portion of the intermediate layer 212 are removed with a laser beam, the length of the hole H(CA) in the first direction (e.g., the x direction or −x direction), which may be formed by the laser beam, may be about 15 um or less. In addition, when the length of the area where the sub-pixel electrode 211 and the opposite electrode 213 contact each other, in the first direction (e.g., the x direction or −x direction), is less than about 3 μm, the area where the sub-pixel electrode 211 and the opposite electrode 213 contact each other may not be sufficient to compensate for the increase in resistance due to the thin opposite electrode 213, and thus defects may be caused in the display device.

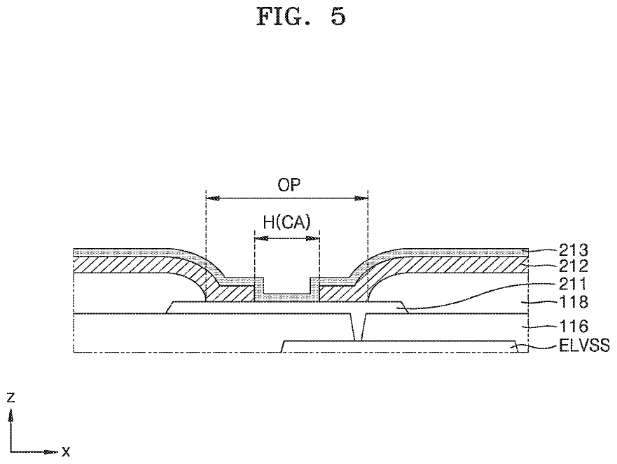

FIG. 5 is a schematic cross-sectional view of a display panel in the case where the thickness of at least a pixel-defining layer located on the upper surface of a sub-pixel electrode exceeds 2,000 Å. FIG. 5 is a diagram for describing an effect of the one or more embodiments corresponding to FIG. 4.

Referring to FIG. 5, when the thickness of at least a portion of the pixel-defining layer 118 located on the upper surface of the sub-pixel electrode 211 exceeds about 2,000 Å, the hole H(CA) may be formed by removing at least a portion of the intermediate layer 212 located on the upper surface of the sub-pixel electrode 211, and the opposite electrode 213 may be located on the sub-pixel electrode 211, and accordingly, the sub-pixel electrode 211 and the opposite electrode 213 may contact each other in the hole H(CA). Because an area where the sub-pixel electrode 211 and the opposite electrode 213 contact each other is formed in an area in which at least a portion of the sub-pixel electrode 211 is exposed by the opening OP of the pixel-defining layer 118, it may be difficult to compensate for the increase in resistance of the display device by contacting the opposite electrode 213 and the sub-pixel electrode 211 applied with the common power voltage ELVSS in the hole H(CA) while maintaining the emission area and the high resolution of the display device.

Referring to FIG. 4, in one or more embodiments, the thickness of at least a portion of the pixel-defining layer 118 located on the upper surface of the sub-pixel electrode 211 may be about 2,000 Å or less such that the hole H(CA) may be formed by concurrently or substantially simultaneously removing at least a portion of the pixel-defining layer 118 and at least a portion of the intermediate layer 212, which are located on the upper surface of the sub-pixel electrode 211, with laser beam irradiation. For example, as illustrated in FIG. 4, because an area that the sub-pixel electrode 211 applied with the common power voltage ELVSS and the opposite electrode 213 contact each other are secured by forming the hole H(CA) in an area 211a (e.g., an area corresponding to the entire upper surface of the sub-pixel electrode 211) up to a portion where the pixel-defining layer 118 is located on the upper surface of the sub-pixel electrode 211, instead of an area that the sub-pixel electrode 211 is exposed by the opening OP of the pixel-defining layer 118, the increase in resistance of the display device may be compensated while maintaining the emission area and the high resolution of the display device, and thus the reliability and the quality of the display device may be improved.

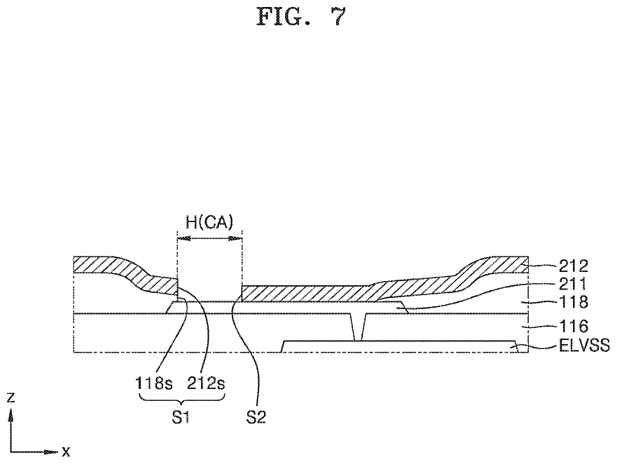

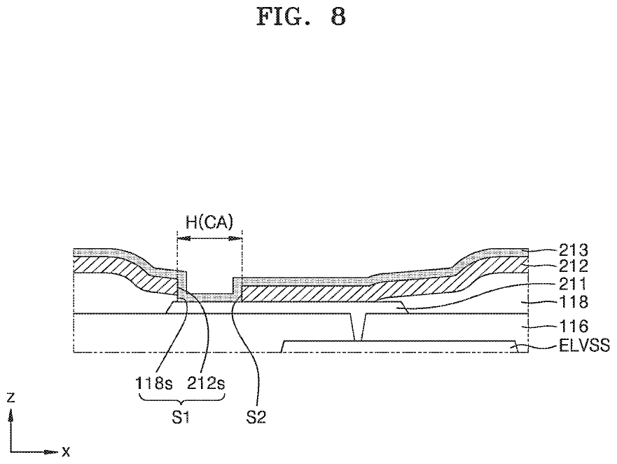

FIGS. 6A, 7, and 8 are schematic cross-sectional views showing a method of manufacturing a display device. FIG. 6B is an enlarged view schematically showing a region A of FIG. 6A.

Referring to FIGS. 6A, 6B, 7, and 8, the sub-pixel electrode 211 may be located on the second organic insulating layer 116. The pixel-defining layer 118 may be located on the sub-pixel electrode 211. The intermediate layer 212 may be located on the sub-pixel electrode 211 and the pixel-defining layer 118. The intermediate layer 212 may include an emission layer and a functional layer.

At least a portion of the pixel-defining layer 118 and at least a portion of the intermediate layer 212 may be located on the upper surface of the sub-pixel electrode 211. The hole H(CA) may be formed by irradiating a laser beam through the laser 30 to at least a portion of the pixel-defining layer 118 and at least a portion of the intermediate layer 212, which are located on the upper surface of the sub-pixel electrode 211. For example, the hole H(CA) may be formed by concurrently or substantially simultaneously removing the portion of the pixel-defining layer 118 and the portion of the intermediate layer 212, which are located on the upper surface of the sub-pixel electrode 211, by light emitted by the laser 30.

The intensity of light irradiated by the laser 30 may be about 200 mJ/cm² or less. When the intensity of light irradiated by the laser 30 exceeds about 200 mJ/cm², the sub-pixel electrode 211 may burst, and defects may be caused in the display device. In addition, the wavelength of light irradiated by the laser 30 is the wavelength of an ultraviolet area, and may be, for example, about 300 nm or more and about 400 nm or less. The laser 30 irradiating light having the wavelength of the ultraviolet area may be used to efficiently remove at least a portion of the pixel-defining layer 118 and at least a portion of the intermediate layer 212, which are located on the upper surface of the sub-pixel electrode 211, without damaging the lower portion of the display panel.

In one or more embodiments, a thickness t2 of at least a portion of the pixel-defining layer 118, which is located on the upper surface of the sub-pixel electrode 211, may be about 2,000 Å or less. For example, the thickness t2 of the portion of the pixel-defining layer 118, which is located on the upper surface of the sub-pixel electrode 211, may be about 100 Å or more and about 2,000 Å or less.

When the laser 30 irradiates light having the wavelength of the ultraviolet area, and the intensity of light is about 200 mJ/cm² or less, the thickness of the pixel-defining layer 118 and the intermediate layer 212, which may be removed, may be about 6,000 Å. Because the thickness of the intermediate layer 212 is about 4,000 Å, the thickness t2 of at least a portion of the pixel-defining layer 118, which is located on the upper surface of the sub-pixel electrode 211, may be about 2,000 Å or less to form the hole H(CA) by concurrently or substantially simultaneously removing the pixel-defining layer 118 and the intermediate layer 212, which are located on the upper surface of the sub-pixel electrode 211, with the laser 30. When the thickness t2 of at least a portion of the pixel-defining layer 118, which is located on the upper surface of the sub-pixel electrode 211, exceeds about 2,000 Å, the hole H(CA) may not be formed by concurrently or substantially simultaneously removing at least a portion of the pixel-defining layer 118 and at least a portion of the intermediate layer 212, which are located on the upper surface of the sub-pixel electrode 211.

The reflective film of the sub-pixel electrode 211 may include Ag, and a layer including a conductive oxide may be located on the lower portion and the upper portion of the reflective film. When the side surface of the sub-pixel electrode 211 is exposed, because a side surface of the reflective film included in the sub-pixel electrode 211 is exposed, the reflective film including Ag may be oxidized in a manufacturing process of a display panel, and the sub-pixel electrode 211 may be dissolved. To reduce or prevent the likelihood of the dissolution of the sub-pixel electrode 211, the side surface of the reflective film of the sub-pixel electrode 211 may be covered with the pixel-defining layer 118. Because the edge portion (or the side surface portion) of the sub-pixel electrode 211 may be covered with the pixel-defining layer 118, at least a portion of the pixel-defining layer 118 may also be located on the upper surface of the sub-pixel electrode 211, which is adjacent to the edge portion (or the side surface portion) of the sub-pixel electrode 211. Accordingly, the thickness t2 of the portion of the pixel-defining layer 118, which is located on the upper surface of the sub-pixel electrode 211, may be about 100 Å or more. When the thickness t2 of the portion of the pixel-defining layer 118, which is located on the upper surface of the sub-pixel electrode 211, is less than about 100 Å, the side surface of the sub-pixel electrode 211 may not be covered with the pixel-defining layer 118, and accordingly, the sub-pixel electrode 211 may be dissolved, and defects may be caused in the display device.

In one or more embodiments, a length t1 of an area where the pixel-defining layer 118 is located on the sub-pixel electrode 211, in the first direction (e.g., the x direction or −x direction), may be about 1 μm or more. In other words, the length t1 between an end of the sub-pixel electrode 211 and an end of the pixel-defining layer 118 above the upper surface of the sub-pixel electrode 211, in the first direction (e.g., the x direction or −x direction), may be about 1 μor more. When the length t1 of an area in which the pixel-defining layer 118 is located on the sub-pixel electrode 211, in the first direction (e.g., the x direction or −x direction), exceeds about 1 μm, as described above, then the side surface of the sub-pixel electrode 211 may not be covered with the pixel-defining layer 118, and accordingly, the sub-pixel electrode 211 may be dissolved in a manufacturing process of the display device, and defects may be caused in the display device.

At least a portion of the sub-pixel electrode 211 may be exposed by the hole H(CA) defined in at least a portion of the pixel-defining layer 118 and at least a portion of the intermediate layer 212, which are located on the upper surface of the sub-pixel electrode 211. The opposite electrode 213 may be located on the sub-pixel electrode 211, and the hole H(CA) may be an area where the sub-pixel electrode 211 and the opposite electrode 213 contact each other. The common power voltage ELVSS may be applied to the sub-pixel electrode 211. In the case of a large display, an increase in resistance due to the thin opposite electrode 213 may result in a voltage drop (IR drop) phenomenon when power is applied to the sub-pixel circuit PC. The increase in resistance due to the thin opposite electrode 213 may be compensated by contacting the opposite electrode 213 and the sub-pixel electrode 211 applied with the common power voltage ELVSS with each other, and the reliability of the display device may be secured.

A length of the hole H(CA) in the first direction (e.g., the x direction or −x direction) may be about 3 μm or more and about 15 μm or less. For example, a length of an area where the sub-pixel electrode 211 and the opposite electrode 213 contact each other in the hole H(CA), in the first direction (e.g., the x direction or −x direction), may be about 3 μm or more and about 15 μm or less. The hole H(CA) may be formed by irradiating light to at least a portion of the pixel-defining layer 118 and at least a portion of the intermediate layer 212, which are located on the upper surface of the sub-pixel electrode 211, through the laser 30, and by removing the portion of the pixel-defining layer 118 and the portion of the intermediate layer 212, which are irradiated by the light. When at least a portion of the pixel-defining layer 118 and at least a portion of the intermediate layer 212 are removed with the laser 30, the length of the hole H(CA) in the first direction (e.g., the x direction or −x direction), which may be formed by the laser 30, may be about 15 μm or less. In addition, when the length of the area where the sub-pixel electrode 211 and the opposite electrode 213 contact each other, in the first direction (e.g., the x direction or −x direction), is less than about 3 μm, the area where the sub-pixel electrode 211 and the opposite electrode 213 contact each other may not be sufficient to compensate for the increase in resistance due to the thin opposite electrode, and thus defects may be caused in the display device.

In one or more embodiments, the thickness of at least a portion of the pixel-defining layer 118 located on the upper surface of the sub-pixel electrode 211 may be about 2,000 Å or less, such that the hole H(CA) may be formed by concurrently or substantially simultaneously removing at least a portion of the pixel-defining layer 118 and at least a portion of the intermediate layer 212, which are located on the upper surface of the sub-pixel electrode 211, with irradiation of the laser 30. As compared with the case where the thickness of at least a portion of the pixel-defining layer 118, which is located on the upper surface of the sub-pixel electrode 211, exceeds about 2,000 Å, then the voltage drop phenomenon of the display device may be reduced or prevented by electrically connecting the opposite electrode 213 and the sub-pixel electrode 211 applied with the common power voltage ELVSS while maintaining the emission area and the high resolution of the display device, and thus the quality and the reliability of the display device may be improved.

According to the above, a display device with improved reliability and quality and a method of manufacturing the display device may be implemented. The scope of the disclosure is not limited by these effects.

It should be understood that embodiments described herein should be considered in a descriptive sense only and not for purposes of limitation. Descriptions of aspects within each embodiment should typically be considered as available for other similar aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display device comprising:
a substrate;
a sub-pixel electrode above the substrate;
a pixel-defining layer partially above the sub-pixel electrode;
an intermediate layer partially above the pixel-defining layer, and defining a hole exposing at least a portion of the sub-pixel electrode; and
an opposite electrode partially above the intermediate layer,
wherein a first side surface defining the hole, which is adjacent to an edge portion of the sub-pixel electrode, comprises a side surface of the pixel-defining layer and a side surface of the intermediate layer.

2. The display device of claim 1, wherein the hole corresponds to an area where the sub-pixel electrode and the opposite electrode contact each other.

3. The display device of claim 1, wherein a thickness of the side surface of the pixel-defining layer is about 2,000 Å or less.

4. The display device of claim 1, wherein a thickness of the side surface of the pixel-defining layer is about 100 Å or more and about 2,000 Å or less.

5. The display device of claim 1, wherein a length of the hole in a first direction is about 3 μm or more and about 15 μm or less.

6. The display device of claim 5, wherein a second side surface of the hole, which is spaced apart from the first side surface in the first direction, comprises only a side surface of the intermediate layer.

7. The display device of claim 6, wherein the second side surface of the hole does not comprise a surface of the pixel-defining layer.

8. The display device of claim 1, wherein the intermediate layer comprises an emission layer and a functional layer.

9. A method of manufacturing a display device, the method comprising:
forming a hole by irradiating a laser beam to a pixel-defining layer and an intermediate layer above an upper surface of a sub-pixel electrode; and
forming an opposite electrode on the sub-pixel electrode,
wherein a thickness of a portion of the pixel-defining layer above the sub-pixel electrode is about 2,000 Å or less.

10. The method of claim 9, wherein the thickness of the portion of the pixel-defining layer is about 100 Å or more.

11. The method of claim 9, wherein the forming of the hole comprises removing, by irradiating the laser beam, another portion of the pixel-defining layer and a portion of the intermediate layer above the sub-pixel electrode.

12. The method of claim 9, wherein the forming of the hole comprises concurrently removing, by irradiating the laser beam, another portion of the pixel-defining layer and a portion of the intermediate layer above the sub-pixel electrode.

13. The method of claim 9, wherein the hole corresponds to an area in which the sub-pixel electrode and the opposite electrode contact each other.

14. The method of claim 9, wherein a length of the hole is about 3 μm or more and about 15 μm or less.

15. The method of claim 9, wherein a length of an area where the pixel-defining layer is above the sub-pixel electrode is about 1 μm or more.

16. The method of claim 9, wherein a length between an end of the sub-pixel electrode and an end of the pixel-defining layer above the sub-pixel electrode is about 1 μm or more.

17. The method of claim 9, wherein the intermediate layer comprises an emission layer and a functional layer.

18. The method of claim 9, wherein a wavelength of the laser beam corresponds to an ultraviolet area.

19. The method of claim 9, wherein a wavelength of the laser beam is about 300 nm or more and about 400 nm or less.

20. The method of claim 9, wherein an intensity of the laser beam is about 200 mJ/cm² or less.
